(19) United States
(12) Patent Application Publication
(10) Pub. No.: US 2022/0349073 A1
(43) Pub. Date: Nov. 3, 2022

(54) PHOTOELECTROCHEMICAL DEVICE AND METHOD FOR PRODUCING HYDROGEN USING THE SAME

(71) Applicant: Industry-Academic Coorporation Foundation, Yonsei University, Seoul (KR)

(72) Inventors: Joo Ho MOON, Seoul (KR); Hyung suk LEE, Seoul (KR); Byung Jun KANG, Seoul (KR); Jei Wan TAN, Seoul (KR); Don Yeong KANG, Seoul (KR); Kyung Min KIM, Seoul (KR)

(21) Appl. No.: 17/661,516

(22) Filed: Apr. 29, 2022

(30) Foreign Application Priority Data
Apr. 29, 2021 (KR) 10-2021-0055495
Apr. 28, 2022 (KR) 10-2022-0053043

(51) Int. Cl. C25B 11/087; C25B 11/02; C25B 11/054; C25B 11/055; C23C 16/455

(52) U.S. Cl. CPC C25B 11/087; C25B 11/02; C25B 11/054; C25B 11/055; C23C 16/45534

(57) ABSTRACT

An electrochemical electrode according to the present invention may prevent agglomeration and desorption of a catalyst even when a catalyst in a particle form is used, because a protective layer containing hydrogel is used, such that stability may be secured, thereby implementing an electrode having a long duration.

### CROSS-REFERENCE TO RELATED APPLICATIONS

The present application claims priority to Korean Patent Application No. 10-2022-0053043 filed on Apr. 28, 2022 and Korean Patent Application No. 10-2021-0055495 filed on Apr. 29, 2021. The entire contents of the above-listed application are hereby incorporated by reference for all purposes.

### TECHNICAL FIELD

The following disclosure relates to an electrochemical electrode having improved stability by preventing agglomeration and desorption of a catalyst and preventing photocorrosion of a light absorption layer and a charge transport layer, and a method of producing gas using the same for electrolysis.

### BACKGROUND

In order to practically use a hydrogen production technology by solar light, a solar-to-hydrogen efficiency (STH) of 10% or more and a low cost equivalent to a fossil fuel-based hydrogen production cost are required, and systems currently being studied may be divided largely into three categories. The first is a powder-type photocatalyst-based system, and in this case, the highest efficiency reported so far is an STH of 1%, which is significantly low, and it is difficult to separate generated oxygen and hydrogen, and thus, its practical use is difficult. In a case of a photovoltaic-electrolysis (PV-EC) system utilizing a voltage obtained from a photovoltaic cell, which is currently the most mature technology, high efficiency of an STH of up to 30% is achieved, but a high cost due to a complex system is an obstacle to the practical use. On the other hand, in a case of a photoelectrode-based photoelectrochemical (PEC) system in which an absorption layer and a catalyst are integrated into one device, a production cost may be reduced using a low-cost material, and it is considered an intermediate process in terms of efficiency and complexity.

Photoelectrochemical water splitting is an eco-friendly method that may generate hydrogen energy using water and solar energy. Therefore, in order to construct an efficient photoelectrochemical system, attempts have been made to increase the efficiency by a method of changing a size and a structure of an electrode or synthesizing a catalyst together with the electrode.

In the photoelectrochemical water splitting process, a design of an electrode having excellent durability is very important because it plays an important role in determining a cost. However, it is very difficult to achieve long-term stability due to corrosion and separation of constituent materials. The stability of the device may be improved to some extent through various strategies such as inserting a functional layer between a catalyst and a protective layer and adjusting an electrolyte composition, but a gradual reduction in photocurrent is still an unavoidable problem. In addition, in a case where a layered protective layer is simply used, it is difficult to transport ions and materials from the electrolyte to the catalyst, and thus, there is still a problem in that an initial current is lowered, resulting in an insignificant increase in driving time.

Therefore, research and development for practical use of an electrochemical electrode have been still demanded.

### SUMMARY

An embodiment of the present invention is directed to providing an electrochemical electrode having a long duration by securing stability.

Another embodiment of the present invention is directed to providing an electrochemical electrode that may physically prevent desorption of a catalyst, which is a major cause of deterioration of electrode stability, and may suppress photocorrosion.

In one general aspect, an electrochemical electrode includes: a transparent electrode layer; a gas generating electrode including a catalyst material layer positioned on the transparent electrode layer; and a hydrogel protective layer covering the gas generating electrode, wherein the hydrogel protective layer is conformally bonded to the gas generating electrode.

In the electrochemical electrode according to an exemplary embodiment of the present invention, the electrochemical electrode may comprise a light absorption layer and a charge transport layer formed between the transparent electrode layer and the catalyst material layer.

In the electrochemical electrode according to an exemplary embodiment of the present invention, the light absorption layer may include a material selected from the group consisting of a post-transition metal, a metalloid, and a transition metal.

In the electrochemical electrode according to an exemplary embodiment of the present invention, the charge transport layer may include a metal or a metal oxide, and the catalyst material layer may include at least one catalyst selected from the group consisting of a metal and an oxide thereof, a nitride, an oxynitride, a carbide, a sulfide, a phosphide, and an alloy.

In the electrochemical electrode according to an exemplary embodiment of the present invention, a thickness of the hydrogel protective layer may be 10 to 2,000 μm, and a pore diameter of the hydrogel protective layer may be 1 to 1,000 nm.

In the electrochemical electrode according to an exemplary embodiment of the present invention, a surface of the gas generating electrode may have a first region in which the catalyst material layer is positioned and a second region in which the catalyst material layer is not positioned, the hydrogel protective layer may be covalently bonded to a surface of the gas generating electrode, and the hydrogel protective layer may include a multimer having a charge.

In the electrochemical electrode according to an exemplary embodiment of the present invention, the hydrogel protective layer may have rigidity and ductility in which a Pₘₐₓ/P_{f} value is 1 or less when an rₛ value is 0.2 mm or less, in which rₛ is a radius of an initial crack of hydrogel, Pₘₐₓ is a maximum pressure applied to the hydrogel due to expansion of bubbles, and P_{f} is a critical pressure required for a crack of the hydrogel, and a bonding strength of the hydrogel protective layer and the gas generating electrode may be higher than Pₘₐₓ.

In another general aspect, a method of manufacturing an electrochemical electrode includes: (a) preparing a first liquid containing an alkoxy alcohol-based solvent; (b) preparing a second liquid containing a mercapto acid-based solvent and an alkanolamine-based solvent; (c) applying a mixed liquid of the first liquid and the second liquid to a transparent electrode layer to form a light absorption layer; (d) forming a charge transport layer on the light absorption layer formed in (c); (e) forming a catalyst material layer on the charge transport layer formed in (d); and (f) forming a hydrogel protective layer covering a gas generating electrode including the light absorption layer, the charge transport layer, and the catalyst material layer formed in (c) to (e).

In the method of manufacturing an electrochemical electrode according to an exemplary embodiment of the present invention, the mercapto acid-based solvent may be selected from the group consisting of mercaptoacetic acid, mercaptopropionic acid, mercaptobutyric acid, mercaptohexanoic acid, mercaptooctanoic acid, mercaptodecanoic acid, and mercaptododecanoic acid, the alkanolamine-based solvent may be a compound represented by a chemical formula of NH₂—(CH₂)ₘ—OH (m is an integer of 1 to 4), and a molar ratio of the mercapto acid-based solvent to the alkanolamine-based solvent in the second liquid may be 18:1 to 20:1.

In the method of manufacturing an electrochemical electrode according to an exemplary embodiment of the present invention, in (c), the mixed liquid may be coated to the transparent electrode layer, and annealing may be performed in an inert gas atmosphere, and in (d), the charge transport layer may be formed by atomic layer deposition (ALD). In addition, the method of manufacturing an electrochemical electrode may further include, after (e), modifying a surface of the gas generating electrode with 3-(trimethoxysilyl)propyl methacrylate or alkoxysilane amine, and in (f), the hydrogel protective layer may be formed by polymerizing a polymerizable monomer having an amine group and a polyfunctional monomer.

In still another general aspect, there is provided a method of producing gas selected from the group consisting of hydrogen, oxygen, nitrogen, and chlorine using the electrochemical electrode.

Other features and aspects will be apparent from the following detailed description and the drawings.

### BRIEF DESCRIPTION OF THE FIGURES

FIG. 1 is a graph showing electrical properties of an electrode when a concentration of a monomer is changed.

FIG. 2 is a graph showing stability of an electrode when a concentration of a monomer is changed.

FIG. 3 is a graph showing electrical properties of an electrode in a neutral electrolyte (pH 7).

FIG. 4 is a graph showing electrical properties of an electrode in a basic electrolyte (pH 8).

FIG. 5 is a view illustrating a structure of an electrode immediately after being manufactured.

FIG. 6 is a view illustrating a structure of an electrode in which a hydrogel protective layer is not coated after driving for 5 hours.

FIG. 7 is a view illustrating a structure of an electrode in which a hydrogel protective layer is coated after driving for 100 hours.

FIG. 8 is a view obtained by observing formation, growth, and separation of bubbles on a surface without a hydrogel protective layer and a 10% PAAM surface with a high-speed camera.

FIG. 9 is a graph obtained by evaluating stability of an electrode when a concentration of a surfactant is changed.

FIG. 10 is a view obtained by observing bubbles immediately before separation after reaching CFR (hydrogel/electrolyte interface).

FIG. 11 is a view obtained by observing a surface of an electrode in which a hydrogel protective layer having low rigidity is coated.

FIG. 12 is a graph obtained by evaluating stability of the electrode in which the hydrogel protective layer having low rigidity is coated.

FIG. 13 is a graph obtained by evaluating stability of an electrode when a thickness of a hydrogel protective layer is changed.

FIG. 14 is a view obtained by observing a surface of an electrode in which a hydrogel protective layer having a thickness of 100 μm is coated.

FIG. 15 is a view obtained by observing a surface of an electrode in which a hydrogel protective layer having a thickness of 200 μm is coated.

FIG. 16 is a view obtained by observing a surface of an electrode in which a hydrogel protective layer having a thickness of 1,200 μm is coated.

FIG. 17 is a graph obtained by evaluating stability of an electrode when a thickness of a hydrogel protective layer is changed.

FIG. 18 is a graph obtained by evaluating stability of an electrode when a thickness of a hydrogel protective layer is changed.

### DETAILED DESCRIPTION

Hereinafter, an electrochemical electrode and a method of manufacturing the same of the present invention will be described in detail with reference to the accompanying drawings.

The drawings to be provided below are provided by way of example so that the spirit of the present invention can be sufficiently transferred to those skilled in the art. Therefore, the present invention is not limited to the drawings to be provided below, but may be modified in many different forms. In addition, the drawings suggested below may be exaggerated in order to clear the spirit of the present invention.

Technical terms and scientific terms used herein have the general meanings understood by those skilled in the art to which the present invention pertains unless otherwise defined, and a description for the known function and configuration unnecessarily obscuring the gist of the present invention will be omitted in the following description and the accompanying drawings.

In addition, unless the context clearly indicates otherwise, the singular forms used in the specification are intended to include the plural forms.

The terms “first”, “second”, and the like in the present specification are not used as limiting meanings, but are used to distinguish one component from another component.

The terms “comprise(s)”, “include(s)”, “have (has)”, and the like used in the present specification indicate the presence of described features or components in the specification, and do not preclude the addition of one or more other features or components, unless specifically limited.

In the present specification, it will be understood that when an element such as a film (layer), a region, or a component is referred to as being “on” or “above” another element, it may be directly on another element while being in contact therewith or another film (layer), another region, or another component may be interposed therebetween.

An electrochemical electrode according to the present invention includes: a transparent electrode layer; a gas generating electrode including a catalyst material layer positioned on the transparent electrode layer; and a hydrogel protective layer covering the gas generating electrode, and the hydrogel protective layer is conformally bonded to the gas generating electrode.

In a specific example, the electrochemical electrode may further include a light absorption layer and a charge transport layer formed between the transparent electrode layer and the catalyst material layer.

In a specific example, the light absorption layer may include a material selected from the group consisting of a post-transition metal, a metalloid, and a transition metal. The type of the post-transition metal may be selected from the group consisting of Ga, In, Sn, Tl, Pb, and Bi, the type of the metalloid may be selected from the group consisting of Ge, Sb, and Te, and the type of the transition metal may be selected from the group consisting of Sc, Ti, V, Cr, Mn, Fe, Co, Ni, Cu, Zn, Y, Zr, Nb, and Mo. In addition, the light absorption layer may include chalcogenide containing a material selected from the group consisting of a post-transition metal, a metalloid, and a transition metal, and an oxide thereof. The type of chalcogen may be selected from the group consisting of sulfur (S), selenium (Se), and tellurium (Te). A light absorption layer having a low band gap energy is significantly advantageous for absorption of solar light, and in particular, absorption of a long wavelength. More specifically, it is advantageous for absorption of solar light when the band gap energy is 1.50 eV or less, more preferably 1.40 eV or less, and most preferably 1.25 eV or less.

In a specific example, the charge transport layer may be formed of a metal or a metal oxide, and the metal or the metal oxide may be preferably a Group 4 metal or a Group 4 metal oxide, and more preferably, the Group 4 metal may be titanium (Ti) or zirconium (Zr) and more preferably Ti. Therefore, the Group 4 metal oxide may be TiO₂ or ZrO₂ and preferably TiO₂. When TiO₂ receives light energy corresponding to the band gap, electrons are excited from a valence band (VB) to a conduction band (CB), and holes are left in the valence band. The holes generated in the valence band form an OH radical on a TiO₂ surface and react with substrates adsorbed to a surface of a catalyst to oxidize organic matters. When the holes return to the original state by an oxidation reaction with the substrates adsorbed to the surface of the catalyst, the electrons excited to the conduction band lose recombination sites and donate electrons to Ti(IV) adjacent to the surface or Ti inside the catalyst to reduce the IV-valence state to the III-valence state. Upon this principle, TiO₂ may be used for a charge transport layer of the electrode.

In a specific example, the catalyst material layer may include at least one catalyst selected from the group consisting of a metal and an oxide thereof, a nitride, an oxynitride, a carbide, a sulfide, a phosphide, and an alloy. The metal may include at least one of Pt, Ti, Sn, Zn, Mn, Mg, Ni, W, Co, Fe, Ba, In, Zr, Cu, Al, Bi, Pb, Ag, Cd, Ga, Y, Mo, Rh, Pd, Sb, Cs, La, V, Si, Al, and Sr. Since the band gap of TiO₂ is 3.0 to 3.2 eV, light in an ultraviolet region having a wavelength shorter than 388 nm is required to overcome this band gap. However, the ultraviolet region included in the solar light is only less than 5%. Therefore, as one of the methods for using light in a visible light region that accounts for most of the solar light, platinum is used to facilitate electron transport from the conduction band of TiO₂ to a material that receives electrons, such that a recombination of the electron and the hole is reduced to improve the overall reaction rate.

In addition, the catalyst material layer may be formed of a catalyst in a thin film form or a particle form, and a catalyst in a particle form may be zero-dimensional particles or an agglomeration of zero-dimensional particles. Here, a diameter of the catalyst in the particle form may be 1 to 20 nm, preferably 1 to 10 nm, and more preferably 1 to 5 nm.

In a specific example, a surface of the charge transport layer may have a first region in which the catalyst material layer is positioned and a second region in which the catalyst material layer is not positioned. Therefore, the hydrogel protective layer may be in contact with the first region in which the catalyst material layer is positioned, and may be in contact with the second region in which the catalyst material layer is not positioned. As described below, in the first region, the hydrogel protective layer may be positioned as a protective layer on the catalyst material layer to stably protect the catalyst in a thin film form, a zero-dimensional particle form, or an agglomeration form of zero-dimensional particles, and in the second region, the hydrogel protective layer may form a covalent bond with the surface of the gas generating electrode.

Here, an area ratio of the first region to the second region may be preferably 100:1 to 1:100, more preferably 70:1 to 1:70, still more preferably 40:1 to 1:40, and most preferably 10:1 to 1:10.

In a specific example, the hydrogel protective layer covering the gas generating electrode may be produced by polymerizing a polymerizable monomer having an amine group and a polyfunctional monomer. That is, a hydrogel protective layer having a three-dimensional network structure formed by crosslinking of a polymerizable monomer having an amine group and a polyfunctional monomer may be stably coated to the gas generating electrode. The catalyst used in the electrode is preferably used in a particle form rather than a thin film form, but in the case of the catalyst in the particle form, adhesion to the electrode may be insufficient. In order to overcome this disadvantage, a three-dimensional network structure may be formed by coating the hydrogel protective layer to the gas generating electrode to implement physical bonding, and as described below, covalent bonding may be performed to implement chemical bonding.

As the polymerizable monomer for producing the hydrogel protective layer, any polymerizable monomer may be applied without limitation as long as it has an amine group, and specifically, an acrylamide or methacrylamide monomer may be applied.

A thickness of the hydrogel protective layer may be preferably 10 to 2,000 μm, more preferably 30 to 1,500 μm, and still more preferably 50 to 1,200 μm. When the thickness of the hydrogel protective layer is 10 to 2,000 μm, bubbles generated in the gas generating electrode easily escape from the hydrogel protective layer, and a phenomenon in which larger bubbles are formed does not occur, such that stability is improved.

A pore diameter of the hydrogel protective layer may be preferably 1 to 1,000 nm, more preferably 2 to 100 nm, still more preferably 3 to 50 nm, still more preferably 4 to 40 nm, and most preferably 5 to 30 nm. When the pore diameter of the hydrogel protective layer is in the above range, the network is dense and bubbles generated in the gas generating electrode easily escape from the hydrogel protective layer, such that stability is improved.

The hydrogel protective layer may be preferably polymerized using an aqueous solution of a monomer having a concentration of 8 to 20 vol %, may be more preferably polymerized using an aqueous solution of a monomer having a concentration of 8 to 16 vol %, and may be most preferably polymerized using an aqueous solution of a monomer having a concentration of 8 to 12 vol %. When the hydrogel protective layer is polymerized using an aqueous solution of a monomer having a concentration of 8 to 20 vol %, bubbles generated in the gas generating electrode easily escape from the hydrogel protective layer, and a phenomenon in which larger bubbles are formed does not occur, such that stability is improved.

The hydrogel protective layer is synthesized by crosslinking of a monomer and a crosslinking agent. Here, a molar ratio of the monomer to the crosslinking agent may be preferably 60:1 to 100:1, more preferably 70:1 to 90:1, and most preferably 75:1 to 85:1.

The hydrogel protective layer may be conformally bonded to the gas generating electrode. The hydrogel is densely formed along the surface of the gas generating electrode and the hydrogel is bonded to the gas generating electrode, such that desorption of the hydrogel from the gas generating electrode is prevented, and bubbles generated in the gas generating electrode easily escape from the hydrogel protective layer, thereby improving stability of the electrochemical electrode.

In addition, the hydrogel protective layer may be covalently bonded to the surface of the gas generating electrode to form a coating layer. The gas generating electrode may be covalently bonded to a compound having a reactivity to the surface of the gas generating electrode to form a self-assembled monolayer, and the compound may be activated as described below by further having a reactive functional group.

Specifically, the compound having a reactivity to the surface of the gas generating electrode may be an alkoxysilane amine compound or a compound represented by a chemical formula of Si(OR)₃(CH₂)ₚNH₂ (p is an integer of 1 to 4, and R is hydrogen or a C₁-C₄ alkyl group), and more specifically, may be (3-aminopropyl)triethoxysilane (APTES).

A self-assembled monolayer is formed on the surface of the gas generating electrode with the alkoxysilane amine compound, such that the amine group that is a reactive functional group may be exposed to the surface, and the amine group may be subsequently activated with an aldehyde group. The amine group may be treated with a compound having two to four aldehyde groups for activation of the aldehyde group, such that the amine group may be activated with an aldehyde group. Non-limiting examples of the two to four aldehyde groups include, but are limited to, glutaraldehyde.

The aldehyde group and the amine group of the polymerizable monomer constituting the hydrogel protective layer are covalently bonded to each other, such that the hydrogel protective layer may be stably covalently bonded to the surface of the gas generating electrode. Since the hydrogel protective layer is selectively covalently bonded to the surface of the gas generating electrode through the covalent bonding as described above, and does not form a covalent bond with the catalyst material layer, hydrogen bubbles generated on a surface of the catalyst material layer may be rapidly desorbed, and the hydrogel protective layer stably protects the catalyst material layer, such that desorption of the catalyst material layer may be effectively suppressed, which is preferable.

In addition, the hydrogel protective layer includes a multimer having a charge, such that elements constituting the gas generating electrode are dissolved and movement of generated ions is suppressed, and thus, dissolution of the surface of the electrode may be suppressed, which is preferable.

As a result, the hydrogel protective layer is effective not only in preventing desorption of the catalyst present on the surface of the gas generating electrode, but also in suppressing dissolution of additional metal ions by the Le Chatelier's principle due to a high concentration of metal ions dissolved from the vicinity of the surface of the electrode coated by the hydrogel protective layer.

In a specific example, as the reaction proceeds in the electrochemical electrode, bubbles are generated, and a pressure applied to the hydrogel is increased due to expansion of the generated bubbles. Here, a maximum pressure (Pₘₐₓ) applied to the hydrogel due to expansion of the bubbles may be calculated by the following Equation 1:

$${P}_{f} = {( \frac{π {EG}_{c}}{\text{?}} )}^{0.5} {( \frac{1}{\text{?}} )}^{0.5} \qquad Equation 2$$

$$\text{?} \text{indicates text missing or illegible when filed}$$

(wherein rₛ represents a radius of an initial crack of hydrogel, E represents a modulus of elasticity of the hydrogel, and y represents a surface energy (0.072 J/m²) of the hydrogel).

In addition, a critical pressure required for a crack of the hydrogel may be calculated by the following Equation 2:

$$P \text{?} = \frac{5}{\text{?}} E + \frac{2 γ}{\text{?}} \qquad Equation 1$$

$$\text{?} \text{indicates text missing or illegible when filed}$$

(wherein G_{c} represents a critical energy-release ratio of hydrogel).

That is, when the pressure applied to the hydrogel protective layer is higher than the critical pressure, bubbles are expanded, resulting in generation of cracks in the hydrogel.

The hydrogel protective layer may have rigidity and ductility in which a Pₘₐₓ/P_{f} value is 1 or less when the rₛ value is 0.2 mm or less. When the Pₘₐₓ/P_{f} ratio is 1 or more, cracks are generated in the hydrogel protective layer due to generated bubbles. When the cracks are generated in the hydrogel protective layer, the surface of the electrode is not protected and damaged, and thus, a current is gradually decreased. Therefore, when the bonding strength of the hydrogel protective layer and the gas generating electrode is higher than Pₘₐₓ, the hydrogel protective layer is not easily desorbed.

The present invention provides a method of producing gas selected from the group consisting of hydrogen, oxygen, nitrogen, and chlorine by irradiating the electrochemical electrode with light.

A method of manufacturing an electrochemical electrode according to the present invention includes: (a) preparing a first liquid containing an alkoxy alcohol-based solvent; (b) preparing a second liquid containing a mercapto acid-based solvent and an alkanolamine-based solvent; (c) applying a mixed liquid of the first liquid and the second liquid to a transparent electrode layer to form a light absorption layer; (d) forming a charge transport layer on the light absorption layer formed in (c); (e) forming a catalyst material layer on the charge transport layer formed in (d); and (f) forming a hydrogel protective layer covering a gas generating electrode including the light absorption layer, the charge transport layer, and the catalyst material layer formed in (c) to (e).

In a specific example, the first liquid prepared in (a) may contain an alkoxy alcohol-based solvent as a solvent. The alkoxy alcohol-based solvent may be a solvent selected from 2-methoxyethanol, 2-methoxypropanol, and 3-methoxypropanol. A concentration of the first liquid may be preferably 0.02 to 0.4 M, more preferably 0.04 to 0.3 M, still more preferably 0.06 to 0.2 M, and most preferably 0.08 to 0.1 M, but is not limited thereto.

In a specific example, the second liquid prepared in (b) may contain an alkanolamine-based solvent and a mercapto acid-based solvent as a solvent. The alkanolamine-based solvent may be a compound represented by a chemical formula of NH₂—(CH₂)ₘ—OH (m is an integer of 1 to 4), preferably a compound represented by a chemical formula of NH₂—(CH₂)ₘ—OH (m is an integer of 1 to 4), which is a liquid at room temperature and 1 atm, and most preferably ethanolamine.

In addition, the mercapto acid-based solvent may be a solvent selected from mercaptoacetic acid, mercaptopropionic acid, mercaptobutyric acid, mercaptohexanoic acid, mercaptooctanoic acid, mercaptodecanoic acid, and mercaptododecanoic acid.

A molar ratio of the mercapto acid-based solvent to the alkanolamine-based solvent in the second liquid may be 15:1 to 20:1, preferably 16:1 to 20:1, more preferably 17:1 to 20:1, and most preferably 18:1 to 20:1. A concentration of the second liquid may be preferably 0.2 to 1.0 M, more preferably 0.3 to 0.9 M, still more preferably 0.4 to 0.8 M, and most preferably 0.5 to 0.7 M, but is not limited thereto.

In a specific example, in (c), a mixed liquid obtained by mixing the first liquid and the second liquid may be coated to the transparent electrode layer and annealing may be performed in an inert gas atmosphere to form a light absorption layer.

The coating may be performed by a method commonly used for forming a film by applying a solution in the semiconductor field. As an example, the coating may be performed by spin coating, roll coating, spray coating, blade coating, bar coating, dip coating, or the like, but the present invention is not limited by a specific coating method.

The annealing is performed to improve crystallinity of the light absorption layer generated by application of the solution, and a temperature during first annealing or second annealing may be 150 to 400° C., and specifically, 200 to 350° C., but is not limited thereto. In the annealing, the inert gas atmosphere may be nitrogen, argon, helium, or a mixed gas atmosphere thereof.

In addition, before the annealing, drying for removing the solvent from the applied solution may be performed. Specifically, the drying may be performed at a temperature of 180 to 300° C., and may be performed for 1 to 10 minutes. More specifically, the drying may be multi-stage drying including primary drying performed at a temperature of 150 to 200° C. and secondary drying performed at a temperature of 280 to 320° C. In the multi-stage drying, the primary drying and the secondary drying may be performed independently of each other for 1 to 5 minutes, but the present invention is not limited by the drying time.

In a specific example, in (d), the charge transport layer may be formed by atomic layer deposition (ALD). The atomic layer deposition is a technology capable of depositing a thin film at a level of an atomic layer, and is a method of chemically adsorbing introduced source gas to a surface of a substrate, purging the remaining source gas, and then forming a material layer from the adsorbed source gas. According to this method, a thickness of the material layer may be adjusted in unit of an atomic layer, such that a material layer having excellent step coverage may be formed, and a concentration of impurities contained in the material layer may be significantly lowered.

In a specific example, TiO₂ may be used as a metal oxide, and a precursor as a Ti source in the atomic layer deposition may be selected from the group consisting of tetraisopropoxy titanium, tetrapropoxy titanium, and tetrakis(dimethylamido)titanium (TDMAT), and may be preferably TDMAT. In addition, the TiO₂ charge transport layer may be deposited on the light absorption layer using H₂O as an O source through atomic layer deposition.

In a specific example, in (e), the catalyst material layer may be formed by sputtering a catalyst. In addition, the method may further include, after (e), modifying a surface of the gas generating electrode with 3-(trimethoxysilyl)propyl methacrylate or alkoxysilane amine.

In the method of manufacturing an electrode, in (f), the hydrogel protective layer may be produced by polymerizing a polymerizable monomer having an amine group and a polyfunctional monomer. As the polymerizable monomer for producing the hydrogel protective layer, any polymerizable monomer may be applied without limitation as long as it has an amine group. Specifically, the polymerizable monomer may be acrylamide or methacrylamide, but is not limited thereto. In (e), the activated aldehyde group and the amine group of the polymerizable monomer having an amine group that constitutes the hydrogel protective layer may be physically bonded or chemically bonded to each other through covalent bonding.

Hereinafter, the present invention will be described in detail with reference to Examples. However, these Examples are intended to describe the present invention in more detail, and the scope of the present invention is not limited by the following Examples.

### Example: Manufacturing of Electrochemical Electrode

### 1. Manufacturing of Gas Generating Electrode

An Sb₂Se₃ electrode was manufactured by spin coating performed on Au-coated FTO glass having a thickness of 70 nm. Sb₂Se₃ was selected for a light absorption layer because it was a low-cost material capable of collecting solar photons having a wavelength of up to 1,050 nm.

First, 0.258 g of SbCl₃ was dissolved in 12 mL of 2-methoxy ethanol. In addition, 0.385 g of Se powder was dissolved in 8 mL of a solution in which thioglycolic acid (TGA) and ethanol amine (EA) were mixed at a molar ratio (TGA:EA) of 95:5. The two solutions were mixed to obtain 20 mL of an Sb—Se solution, and the Sb—Se solution was magnetically stirred at 80° C. overnight.

10 cycles of the spin coating were performed. Each cycle includes spin coating of the Sb—Se solution at 2,000 rpm for 30 seconds and sequential drying of the Sb—Se solution in two steps at 180° C. and 300° C. for 3 minutes, respectively. Thereafter, the sample was subjected to a heat treatment at 350° C. for 20 minutes. In order to prevent an unnecessary oxidation reaction, the spin coating and the heat treatment were performed under N₂ conditions. Finally, a heat treatment was performed in air at 200° C. for 30 minutes to burn residual organic matters.

The TiO₂ layer was deposited on the Sb₂Se₃ layer using tetrakis(dimethylamido)titanium (TDMAT) and water as Ti and O sources, respectively. 600 cycles of the deposition were performed. Each cycle includes TDMAT pulse for 0.3 seconds, N₂ purging for 15 seconds, H₂O pulse for 0.2 seconds, and N₂ purging for 15 seconds. An approximate growth rate of TiO₂ was 0.58 Å/cycle.

A Pt cocatalyst was sputtered on the TiO₂/Sb₂Se₃ electrode under an applied current of 10 mA for 120 seconds.

### 2. Treatment of Surface of Gas Generating Electrode

A surface of the Pt/TiO₂/Sb₂Se₃ electrode was treated with sodium hydroxide (NaOH), (3-aminopropyl)triethoxysilane (APTES), and glutaraldehyde for chemical bonding between polyacrylamide (PAAM) hydrogel and a PEC device.

A 1 N NaOH solution and a 50 vol % glutaraldehyde solution were diluted with deionized (DI) water to prepare a 0.1 N NaOH solution and a 0.5 vol % glutaraldehyde solution, and an APTES solution was diluted with an ethanol solution to prepare a 0.5 vol % APTES solution. The prepared Pt/TiO₂/Sb₂Se₃ electrode was immersed in the 0.1 N NaOH solution for 5 minutes. The NaOH solution was removed, and then, the 0.5 vol % APTES solution was poured into the electrode for 5 minutes. The APTES solution was removed, and then, the electrode was washed six times with an ethanol solution. After the washing, the 0.5 vol % glutaraldehyde solution was poured into the electrode for 30 minutes. The glutaraldehyde solution was removed from the electrode, and the electrode was washed six times with deionized water and then was dried at 60° C. for 30 minutes.

### 3. Deposition of PAAM Hydrogel Protective Layer to Gas Generating Electrode

A PDMS mold was prepared by cutting a silicone rubber thin film. The PDMS mold was washed using ethanol, dust was removed using a double-sided tape, and then, the PDMS mold was placed on the surface-treated electrode. A 100% w/v acrylamide (AAM) solution was prepared by dissolving 1 g of acrylamide powder in 1 mL of DI. A 2% w/v N,N′-methylenebisacrylamide (bis-acrylamide) solution was prepared by dissolving 20 mg of bis-acrylamide powder in 1 mL of DI. A 10% w/v ammonium persulfate (AP) solution was prepared by dissolving 10 mg of AP powder in 100 μL of DI. The acrylamide solution, the bis-acrylamide solution, and deionized water were mixed according to Table 1 to prepare a gel solution, and the gel solution was degassed for 1 hour or longer.

TABLE 1

| | Monomer concentration (%) | | |
|---|---|---|---|
| Volume (μL) | 6% | 10% | 30% |
| DI water | 888 | 817.4 | 464 |
| 100% AAm | 65.2 | 108.6 | 326 |
| 2% Bis-acrylamide | 40.8 | 68 | 204 |
| 10% AP | 5 | 5 | 5 |
| TEMED | 1 | 1 | 1 |
| Total | 1,000 | 1,000 | 1,000 |

A concentration ratio of the monomer to the crosslinking agent was fixed at 80:1. An AP solution and an N,N,N′,N′-tetramethylethylenediamine (TEMED) solution were added together with a pre-gel solution, and gelation was started. The final concentrations of AP and TEMED were 0.05 wt % and 0.1 wt %, respectively. After 30 minutes of the gelation, the cover glass and the PDMS mold were carefully removed.

### Comparative Example

A gas generating electrode was manufactured in the same manner as that of the Example except that Steps 2 and 3 were not performed.

### Experimental Example 1: Analysis of Electrical Properties of Electrochemical Electrode

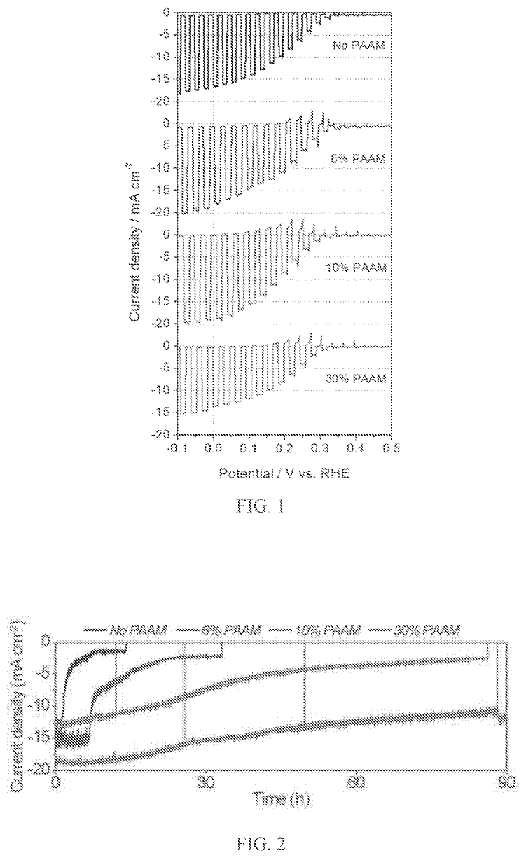

FIG. 1 is a graph showing electrical properties of an electrochemical electrode when a concentration of a monomer constituting a hydrogel protective layer is changed. When the hydrogel was coated to the electrode, there were no significant changes in initial photocurrent density (Jₚₕ) and starting potential at 0V_{RHE}.

However, it could be appreciated that the lifetime of the electrode was significantly extended when the hydrogel protective layer was used.

FIG. 2 is a graph showing stability of an electrode in an acidic (pH 1) electrolyte when a concentration of a monomer constituting a hydrogel protective layer is changed. In a case where a 10% hydrogel protective layer was used, the stability for 90 hours or longer was exhibited while about 70% of the initial photocurrent density was maintained. On the other hand, in the case of the electrochemical electrode according to the Comparative Example, the photocurrent was rapidly reduced, and the surface of the electrode was almost completely damaged within 3 hours. It could be confirmed through this that in the electrode in which the hydrogel protective layer was used, there was no significant difference in initial photocurrent density or starting potential, but the stability was improved by 100 times or more in comparison to the electrode in which the protective layer was not used.

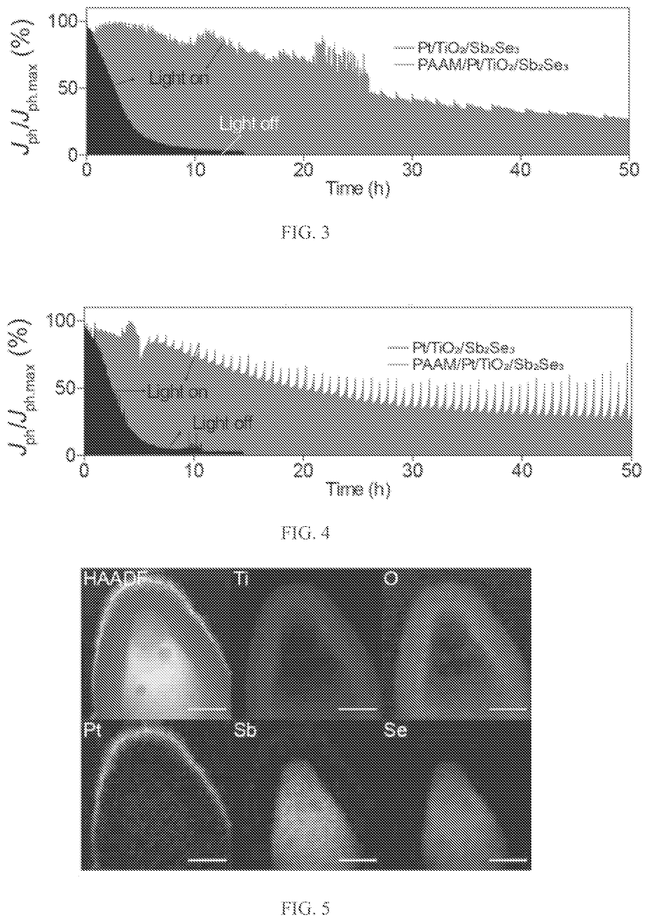

In addition, as illustrated in FIGS. 3 and 4, as a result of testing the stability of the electrode using a neutral (pH 7) electrolyte or a basic (pH 8) electrolyte, as in the case of using the acidic electrolyte, it could be confirmed that the initial photocurrent density was maintained for a long time in the electrode in which the hydrogel protective layer was used, and thus, the electrode and the hydrogel protective layer of the present invention could be used in various electrolytes.

### Experimental Example 2: Analysis of Structure of Electrode

By observing a structure of the surface of the Sb₂Se₃ electrode, it was confirmed that the hydrogel protective layer provided structural stability to the PEC device.

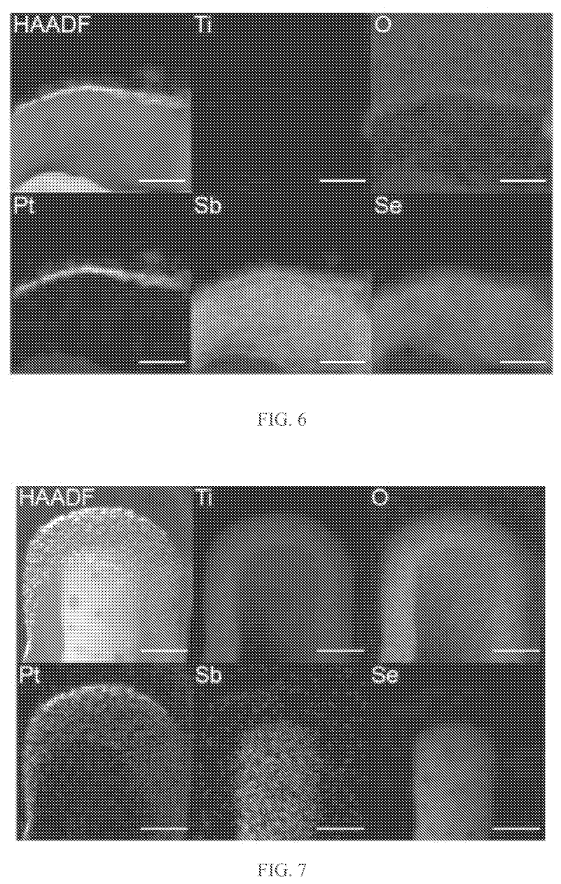

Referring to FIGS. 5 to 7, it could be confirmed that in the case of the electrochemical electrode according to the Comparative Example, after driving for 5 hours, a phenomenon in which Pt was partially separated or agglomerated was observed, and the TiO₂ layer was completely dissolved. On the other hand, it could be confirmed that in the case where the 10% hydrogel protective layer was coated, even after driving for 100 hours, Pt was maintained in the well-attached state, and the TiO₂ layer was also hardly damaged. That is, it was confirmed that the hydrogel protective layer was effective not only in preventing desorption of the platinum particles present on the surface of the gas generating electrode, but also in suppressing dissolution of additional metal ions by the Le Chatelier's principle due to a high concentration of metal ions dissolved from the vicinity of the surface of the electrode coated by the hydrogel protective layer.

### Experimental Example 3: Generation and Separation of Bubbles in Electrode

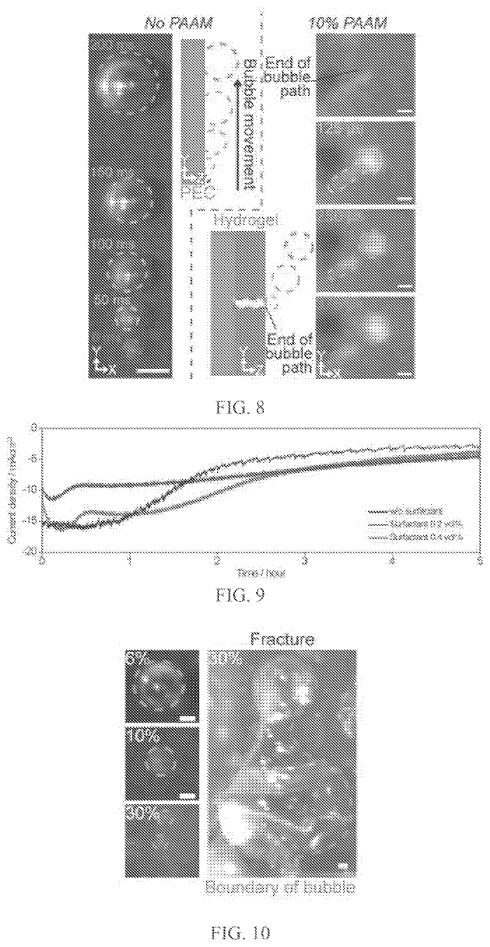

FIG. 8 is a view obtained by observing formation, growth, and separation of bubbles on a surface without a hydrogel protective layer and an electrode surface with a 10% hydrogel protective layer with a high-speed camera.

On the surface of the electrochemical electrode according to the Comparative Example, bubbles grew in a spherical shape within 200 ms. On the other hand, it could be confirmed that in the case of the electrode surface with the 10% hydrogel protective layer, bubbles grew in an elliptical shape to a size similar to the thickness of the hydrogel and reached a confinement-free region (CFR) within 8 seconds, and an elliptical bubble path was formed in a vertical direction of the electrode surface due to separation of the grown bubbles from the hydrogel protective layer. The movement of the bubbles to a region other than the bubble path was hardly observed, which means that hydrogen gas molecules generated on the electrode surface agglomerated and escaped through the bubble path. That is, it was confirmed that in the case of using the 10% hydrogel protective layer, rapid desorption of the hydrogen bubbles generated on the electrode surface was induced.

In addition, in order to determine the role of the hydrogel protective layer for the stability of the electrode, the effect of the separation of the bubbles was analyzed by adding a surfactant to the electrolyte.

FIG. 9 is a graph obtained by evaluating stability of the Pt/TiO₂/Sb₂Se₃ electrode when a concentration of a surfactant is changed. A change in photocurrent due to formation and separation of large bubbles agglomerated from microbubbles was observed. Large bubbles scattered incident light or blocked the electrochemically active region, and thus, the photocurrent density was temporarily lowered. Since the surfactant was added to the electrolyte, formation of large bubbles was prevented and the change in photocurrent was reduced, but the stability was hardly improved. Therefore, it could be appreciated from this that only separation of the bubbles was insufficient to improve the stability.

Finally, it was confirmed that in the case of using the 10% hydrogel protective layer, rapid desorption of the hydrogen bubbles generated on the surface was induced, and the stability was improved due to structural and physical effects provided by the hydrogel network as well as the separation of the bubbles in a condition in which it was difficult to obtain high stability by only the separation of the bubbles.

### Experimental Example 4: Stability Evaluation According to Concentration of Monomer in Hydrogel Protective Layer

The stability of the electrode depends on a concentration of a monomer for producing the hydrogel protective layer. In order to determine how the mechanical properties of the hydrogel contribute to the formation of the bubble path, in the cases of using 6%, 10%, and 30% hydrogel protective layers, generation of hydrogen bubbles in each layer was observed.

FIG. 10 illustrates an image of bubbles immediately before separation after reaching CFR (hydrogel/electrolyte interface). It could be confirmed that in the case of the 6% hydrogel protective layer, the adjacent bubble paths merged with each other to form large bubbles inside the hydrogel network, and abnormally large bubbles covered the entire surface. In the case of the 30% hydrogel protective layer, the hydrogen bubbles were trapped near the electrode/hydrogel protective layer interface or ejected in the form of small bubbles due to the high-density hydrogel network. The bubbles trapped near of the electrode were expanded by additionally generated hydrogen gas and agglomerated to form large bubbles. It was confirmed that the photocurrent was rapidly reduced in the stability test because the large bubbles scattered most of the incident light. On the other hand, it could be confirmed that in the 10% hydrogel protective layer, the bubbles escaped along the bubble path, and abnormally large bubbles were not generated unlike in the 6% or 30% hydrogel protective layer, and thus, the photocurrent was relatively constantly maintained in the stability test.

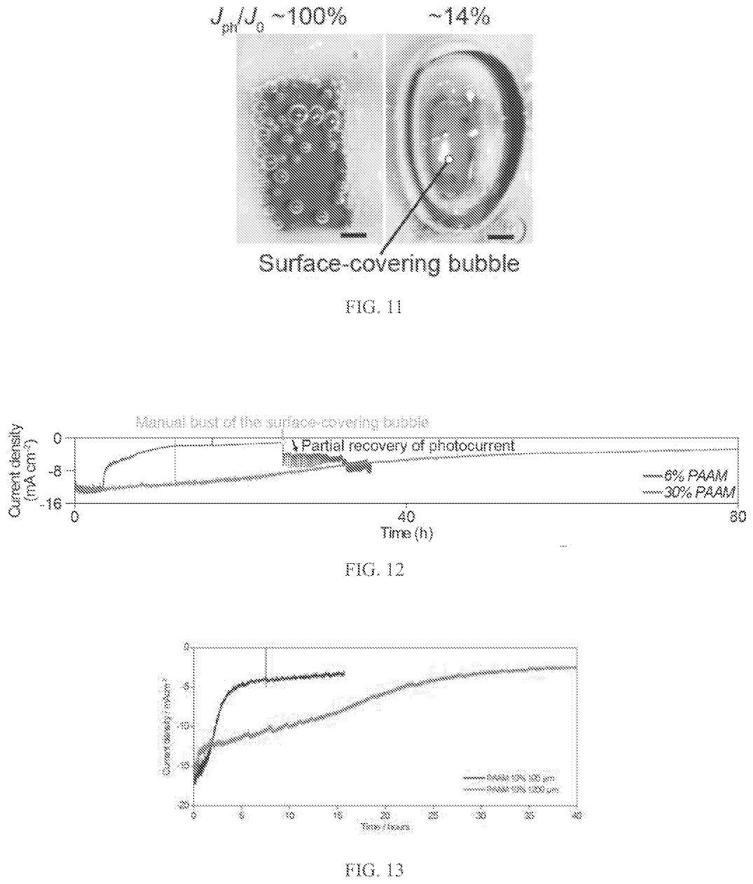

In addition, it was confirmed that in the case of using the hydrogel protective layer having low rigidity obtained using a hydrogel protective layer having a low concentration of a monomer, as illustrated in FIGS. 11 and 12, bubbles were expanded in the hydrogel within the initial few hours, and the entire electrode was covered with the bubbles, and thus, the current was close to zero.

Finally, in the case where a hydrogel protective layer having a specific range of rigidity by adjusting a concentration of a monomer in the hydrogel protective layer was coated, an electrode having excellent stability was manufactured.

### Experimental Example 5: Stability Evaluation According to Thickness of Hydrogel Protective Layer

FIG. 13 is a graph obtained by evaluating stability of a Pt/TiO₂/Sb₂Se₃ electrode when a thickness of a hydrogel protective layer is changed. When the thickness of the hydrogel protective layer was 2,000 μm or more, bubbles initially growing hardly reached the CFR, resulting in agglomeration of large bubbles near the surface. On the other hand, when the thickness of the hydrogel protective layer was decreased to 10 μm, bubbles rapidly reached the CFR, resulting in formation of a relatively large bubble path. Therefore, large bubbles enough to cover the entire PEC device were formed. As the large bubbles were formed, peeling of the protective layer, which was not found under other conditions, was observed. As a result, in the case of using a 10% hydrogel protective layer having a thickness of 100 μm, low stability similar to that in the case in which the protective layer was not used was exhibited.

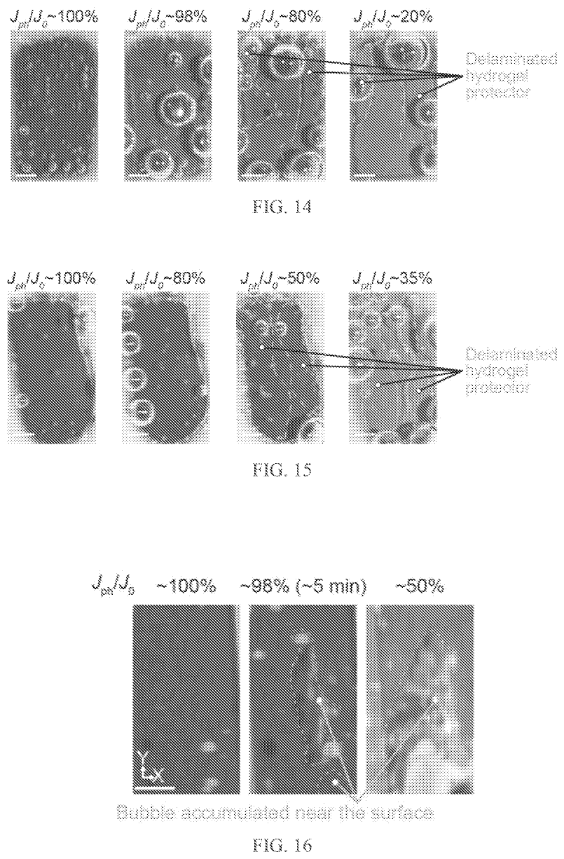

More specifically, in the thin hydrogel protective layer, the pressure due to expansion of the bubbles was concentrated at the interface between the hydrogel protective layer and the device. Therefore, when the maximum pressure (Pₘₐₓ) due to expansion of the bubbles is higher than the bonding strength at the interface between the hydrogel protective layer and the electrode, the hydrogel protective layer was desorbed. In this case, the electrode surface was damaged within a few hours, and the current was also rapidly reduced. Referring to FIGS. 14 and 15, it was confirmed that in the case of including a hydrogel protective layer having a thickness of 100 μm, the hydrogel protective layer was desorbed from the time when Jₚₕ/J₀ was about 80%, but in the case of including a hydrogel protective layer having a thickness of 200 μm, the hydrogel protective layer was desorbed from the time when Jₚₕ/J₀ was about 50%.

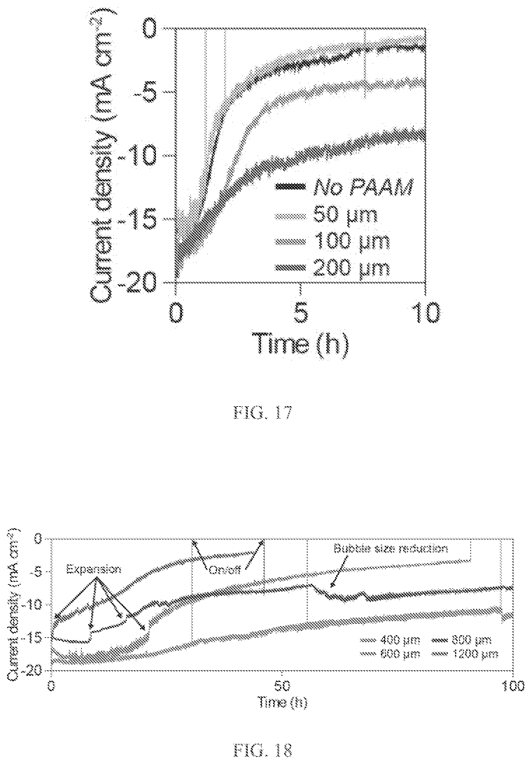

In addition, in the thick hydrogel protective layer, bubbles generated in the device was accumulated while trapped in the hydrogel. As the size of the trapped bubbles was increased, the current was reduced. Referring to FIG. 16, it could be confirmed that when the thickness of the hydrogel protective layer was about 1,200 μm, the bubbles were accumulated on the surface from the time when Jₚₕ/J₀ was about 80%.

Finally, referring to FIGS. 17 and 18, when the thickness of the hydrogel protective layer is within the predetermined range, desorption of the hydrogel protective layer is prevented, and accumulation of the bubbles on the surface is prevented, such that an electrode having excellent stability may be manufactured.

In short, the performance of the electrode described in the present invention has demonstrated through induction of rapid desorption of the hydrogen bubbles generated on the surface and improved stability secured by structural and physical protection, and it is possible to confirm that the electrode according to the present invention has more excellent performance than the electrode according to the related art.

As set forth above, the electrochemical electrode according to the present invention may prevent agglomeration and desorption of the catalyst, such that stability may be secured, thereby implementing an electrode having a long duration. In addition, rapid desorption of bubbles generated on the surface of the electrochemical electrode may be induced, such that a high photocurrent density may be maintained, and a photocorrosion phenomenon may be suppressed. The electrochemical electrode according to the present invention may improve the stability in comparison to the existing electrode by 100 times or more, such that a manufacturing cost of the system may be significantly lowered.

1. An electrochemical electrode comprising:
a transparent electrode layer;
a gas generating electrode including a catalyst material layer positioned on the transparent electrode layer; and
a hydrogel protective layer covering the gas generating electrode,
wherein the hydrogel protective layer is conformally bonded to the gas generating electrode.

2. The electrochemical electrode of claim 1, comprising a light absorption layer and a charge transport layer formed between the transparent electrode layer and the catalyst material layer.

3. The electrochemical electrode of claim 2, wherein the light absorption layer includes a material selected from the group consisting of a post-transition metal, a metalloid, and a transition metal.

4. The electrochemical electrode of claim 2, wherein the charge transport layer includes a metal or a metal oxide.

5. The electrochemical electrode of claim 1, wherein the catalyst material layer includes at least one catalyst selected from the group consisting of a metal and an oxide thereof, a nitride, an oxynitride, a carbide, a sulfide, a phosphide, and an alloy.

6. The electrochemical electrode of claim 1, wherein a thickness of the hydrogel protective layer is 10 to 2,000 μm.

7. The electrochemical electrode of claim 1, wherein a pore diameter of the hydrogel protective layer is 1 to 1,000 nm.

8. The electrochemical electrode of claim 1, wherein a surface of the gas generating electrode has a first region in which the catalyst material layer is positioned and a second region in which the catalyst material layer is not positioned.

9. The electrochemical electrode of claim 1, wherein the hydrogel protective layer is covalently bonded to a surface of the gas generating electrode.

10. The electrochemical electrode of claim 1, wherein the hydrogel protective layer includes a multimer having a charge.

11. The electrochemical electrode of claim 1, wherein the hydrogel protective layer has rigidity and ductility in which a Pₘₐₓ/P_{f} value is 1 or less when an rₛ value is 0.2 mm or less, in which rₛ is a radius of an initial crack of hydrogel, Pₘₐₓ is a maximum pressure applied to the hydrogel due to expansion of bubbles, and P_{f} is a critical pressure required for a crack of the hydrogel.

12. The electrochemical electrode of claim 11, wherein a bonding strength of the hydrogel protective layer and the gas generating electrode is higher than Pₘₐₓ.

13. A method of manufacturing an electrochemical electrode, the method comprising:
(a) preparing a first liquid containing an alkoxy alcohol-based solvent;
(b) preparing a second liquid containing a mercapto acid-based solvent and an alkanolamine-based solvent;
(c) applying a mixed liquid of the first liquid and the second liquid to a transparent electrode layer to form a light absorption layer;
(d) forming a charge transport layer on the light absorption layer formed in (c);
(e) forming a catalyst material layer on the charge transport layer formed in (d); and
(f) forming a hydrogel protective layer covering a gas generating electrode including the light absorption layer, the charge transport layer, and the catalyst material layer formed in (c) to (e).

14. The method of claim 13, wherein the mercapto acid-based solvent is selected from the group consisting of mercaptoacetic acid, mercaptopropionic acid, mercaptobutyric acid, mercaptohexanoic acid, mercaptooctanoic acid, mercaptodecanoic acid, and mercaptododecanoic acid.

15. The method of claim 13, wherein the alkanolamine-based solvent is a compound represented by a chemical formula of NH₂—(CH₂)ₘ—OH (m is an integer of 1 to 4).

16. The method of claim 13, wherein a molar ratio of the mercapto acid-based solvent to the alkanolamine-based solvent in the second liquid is 18:1 to 20:1.

17. The method of claim 13, wherein, in (c), the mixed liquid is coated to the transparent electrode layer, and annealing is performed in an inert gas atmosphere.

18. The method of claim 13, wherein, in (d), the charge transport layer is formed by atomic layer deposition (ALD).

19. The method of claim 13, further comprising, after (e), modifying a surface of the gas generating electrode with 3-(trimethoxysilyl)propyl methacrylate or alkoxysilane amine.

20. The method of claim 13, wherein, in (f), the hydrogel protective layer is formed by polymerizing a polymerizable monomer having an amine group and a polyfunctional monomer.

21. A method of producing gas selected from the group consisting of hydrogen, oxygen, nitrogen, and chlorine using the electrochemical electrode of claim 1.
